(19) United States
(12) Patent Application Publication
(10) Pub. No.: US 2025/0151256 A1
(43) Pub. Date: May 8, 2025

(54) SEMICONDUCTOR STRUCTURE AND METHOD OF FORMING THEREOF

(71) Applicant: NANYA TECHNOLOGY CORPORATION, New Taipei city (TW)

(72) Inventor: Chun-Heng WU, Taoyuan City (TW)

(21) Appl. No.: 18/504,426

(22) Filed: Nov. 8, 2023

(51) Int. Cl. H10B 12/00; H01L 21/768

(52) U.S. Cl. CPC H10B 12/09; H01L 21/76859; H10B 12/488

(57) ABSTRACT

A method includes a number of operations. An oxide layer is formed in an isolation trench over a substrate. A liner is formed over the oxide layer. The liner is oxidized. An implant region is formed over the substrate after the liner is oxidized. The oxide layer and the liner are etched after the implant region is formed. A word line structure is formed over the substrate and across the oxide layer and the liner.

### BACKGROUND

### Field of Invention

The present disclosure relates to semiconductor structures and methods of forming semiconductor structures.

### Description of Related Art

In the manufacturing process of memory devices (e.g., DRAM devices), active area patterns can be defined on a substrate by a hard mask. Oxide material and liner may fill with isolation trenches defined on the substrate. However, unintended bumps may appear on mask layers formed on the oxide material and the liner since the etch rates difference between the oxide material and the liner, and the bumps may influence the designed pattern.

Therefore, how to provide a solution to reduce formation of the unintended bumps is one of the problems those in the industry want to solve.

### SUMMARY

An aspect of the present disclosure is related to a method of forming a semiconductor structure.

According to one or more embodiments of the present disclosure, a method includes a number of operations. An oxide layer is formed in an isolation trench over a substrate. A liner is formed over the oxide layer. The liner is oxidized. An implant region is formed over the substrate after the liner is oxidized. The oxide layer and the liner are etched after the implant region is formed. A word line structure is formed over the substrate and across the oxide layer and the liner.

In one or more embodiments of the present disclosure, the liner is oxidized to have an unoxidized lining portion and an oxidized lining portion over the unoxidized lining portion, and the oxidized lining portion extends into the isolation trench.

In one or more embodiments of the present disclosure, the method further includes forming a semiconductor layer over the substrate and in the isolation trench, wherein the liner is oxidized to have an unoxidized lining portion and an oxidized lining portion over the unoxidized lining portion, and the oxidized lining portion has a bottom surface lower than a top surface of the semiconductor layer.

In one or more embodiments of the present disclosure, the method further includes forming a sacrificial oxide layer over the oxide layer and the liner after the liner is oxidized, wherein the implant region is formed by an implantation process across the sacrificial oxide layer.

In one or more embodiments of the present disclosure, the method further includes a number of operations. A hard mask is formed over the oxide layer and the liner. The hard mask is patterned so that the oxide layer and an oxidized lining portion of the liner are exposed. The oxide layer and the liner are etched based on the hard mask to form a word line trench across the oxide layer and the liner, wherein the word line structure is formed in the word line trench.

In some embodiments, the word line trench is etched so that an oxidized lining portion of the liner is cut off into a first portion and a second portion separated from each other.

In one or more embodiments of the present disclosure, the liner is an oxygen-free layer before the liner is oxidized.

An aspect of the present disclosure is related to a method of forming a semiconductor structure.

According to one or more embodiments of the present disclosure, a method includes a number of operations. A plurality of isolation trenches is formed over a substrate. A first oxide layer is formed over the isolation trenches. A liner is formed over the first oxide layer. A second oxide layer is formed over the liner. The second oxide layer is etched so that the first oxide layer and the liner is exposed. The liner is oxidized. An implant region is formed in the substrate. A word line structure is formed over the substrate and across the isolation trenches.

In one or more embodiments of the present disclosure, the liner is oxidized to have unoxidized lining portions and oxidized lining portions over the unoxidized lining portions, and the oxidized lining portions extend into the isolation trenches.

In some embodiments, after the word line structure is formed, the second oxide layer remains and is between the oxidized lining portions in one of the isolation trenches in a peripheral area free from the word line structure.

In one or more embodiments of the present disclosure, the method further includes forming a sacrificial oxide layer over the first oxide layer, the liner and the second oxide layer after the liner is oxidized, wherein the implant region is formed by an implantation process across the sacrificial oxide layer.

In one or more embodiments of the present disclosure, the method further includes a number of operations. A hard mask is formed over the first oxide layer and the liner. The hard mask is patterned so that the first oxide layer and oxidized lining portions of the liner are exposed. The first oxide layer and the liner are etched based on the hard mask to form a word line trench across the first oxide layer and the liner, wherein the word line structure is formed in the word line trench.

In one or more embodiments of the present disclosure, the liner is an oxygen-free layer before the liner is oxidized.

An aspect of the present disclosure is related to a semiconductor structure.

According to one or more embodiments of the present disclosure, the semiconductor includes a first isolation region and a word line structure. The first isolation region is over a substrate. The first isolation region includes a first oxide layer and a first liner over the first oxide layer. The first liner has a first unoxidized lining portion and a first oxidized lining portion over the first unoxidized lining portion. The word line structure is across the first isolation region. A first portion and a second portion of the first oxidized lining portion are separated from each other by the word line structure.

In one or more embodiments of the present disclosure, the semiconductor structure further includes a second isolation region. The second isolation region is over the substrate. The second isolation region comprises a second liner with a second oxidized lining portion. A first portion and a second portion of the second oxidized lining portion are separated from each other by the word line structure.

In some embodiments, the semiconductor structure further includes an active implant region. The active implant region is between the first oxidized lining portion of the first liner and the second oxidized lining portion of the second liner.

In one or more embodiments of the present disclosure, the semiconductor structure further includes a second isolation region. The second isolation region is over the substrate. The second isolation region includes a second oxide layer, a second liner over the second oxide layer and a third oxide layer over the second liner. The second liner has a second unoxidized lining portion and a second oxidized lining portion over the second unoxidized lining portion. The second oxidized lining portion is between the second oxide layer and the third oxide layer.

In some embodiments, the second isolation region is free from the word line structure.

In one or more embodiments of the present disclosure, a material of the first oxidized lining portion is different from a material of the first oxide layer.

In one or more embodiments of the present disclosure, the semiconductor structure further includes a semiconductor layer. The semiconductor layer is over the substrate. A bottom surface of the first oxidized lining portion is lower than a top surface of the semiconductor layer.

In summary, in one or more embodiments of the present disclosure, an oxidation process may be performed on the liner in the isolation structure. The design pattern of the memory device may not be damaged because of the etch serenity of the liner and the oxide layer and additional planarization processes on the mask layer over the isolation structure can be saved.

It is to be understood that both the foregoing general description and the following detailed description are examples, and are intended to provide further explanation of the disclosure as claimed.

### BRIEF DESCRIPTION OF THE DRAWINGS

The advantages of the present disclosure are to be understood by the following exemplary embodiments and with reference to the attached drawings. The illustrations of the drawings are merely exemplary embodiments and are not to be considered as limiting the scope of the disclosure.

FIG. 1 is a schematic cross-section view of forming an anti-reflective layer and a hard mask over a substrate according to one or more embodiments of the present disclosure;

FIG. 2 is a schematic cross-section view of patterning the hard mask and etching the substrate based on the patterned hard mask according to one or more embodiments of the present disclosure;

FIG. 3 is a schematic cross-section view of removing the hard mask and the anti-reflective layer according to one or more embodiments of the present disclosure;

FIG. 4 is a schematic cross-section view of forming a semiconductor layer over the top surface of the substrate and in the isolation trenches according to one or more embodiments of the present disclosure;

FIG. 5 is a schematic cross-section view of forming a first oxide layer over the semiconductor layer according to one or more embodiments of the present disclosure;

FIG. 6 is a schematic cross-section view of forming a liner over the first oxide layer according to one or more embodiments of the present disclosure;

FIG. 7 is a schematic cross-section view of forming a second oxide layer over the liner according to one or more embodiments of the present disclosure;

FIG. 8 is a schematic cross-section view of polishing the second oxide layer according to one or more embodiments of the present disclosure;

FIG. 9 is a schematic cross-section view of etching the first oxide layer, the liner and the second oxide layer according to one or more embodiments of the present disclosure;

FIG. 10 is a schematic cross-section view of oxidizing the liner according to one or more embodiments of the present disclosure;

FIG. 11 is a schematic cross-section view of forming a sacrificial oxide layer over the first oxide layer and the liner according to one or more embodiments of the present disclosure;

FIG. 12 is a schematic cross-section view of forming an implant region over the substrate according to one or more embodiments of the present disclosure;

FIG. 13 is a schematic cross-section view of removing the sacrificial oxide layer according to one or more embodiments of the present disclosure;

FIG. 14 is a schematic cross-section view of forming a mask layer over the first oxide layer and the liner according to one or more embodiments of the present disclosure;

FIG. 15 is a schematic top view of patterning the mask layer according to one or more embodiments of the present disclosure; and

FIGS. 16A through 16E are schematic top views and cross-section views of a semiconductor structure according to one or more embodiments of the present disclosure.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

In addition, terms used in the specification and the claims generally have the usual meaning as each term is used in the field, in the context of the disclosure and the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the disclosure.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

In a memory device, an active area can be defined by forming multiple isolation structures. In some embodiments, the isolation structure may include multiple oxide layers and liner. For example, the material of the oxide layers may be silicon oxide, and the material of the liner may include silicon nitride. During the manufacturing process of the memory device, since the oxide layer and the liner of the isolation structure are made of different materials with different etching rates, the remaining heights of the oxide layer and the liner may be different after the oxide layers and the liner are etched. When the mask layer is subsequently formed on the isolation structure of the oxide layers and the liner to perform the etching process of formation of word lines of the memory device, a plurality of unintended bumps will be formed on the mask layer due to the difference between the remaining heights of the oxide layer and the liner. The bumps on the mask layer will affect the design pattern of the memory device. In some embodiments, an additional planarization process is performed on the mask layer with the bumps to remove unintended bumps and avoid damage to the designed pattern.

In one or more embodiments of the present disclosure, an oxidation process may be performed on the liner in the isolation structure. The oxidized portion of the liner and the oxide layer can have similar etching rates. After performing the etching process for the formation of the isolation structure of the liner and the oxide layer in a formed isolation trench, the oxide layer and the liner can have similar remaining heights. Therefore, after the mask layer is subsequently formed on the isolation structure, few or no unintended bump is formed on the mask layer. The design pattern of the memory device may not be damaged and additional planarization processes on the mask layer over the isolation structure can be saved.

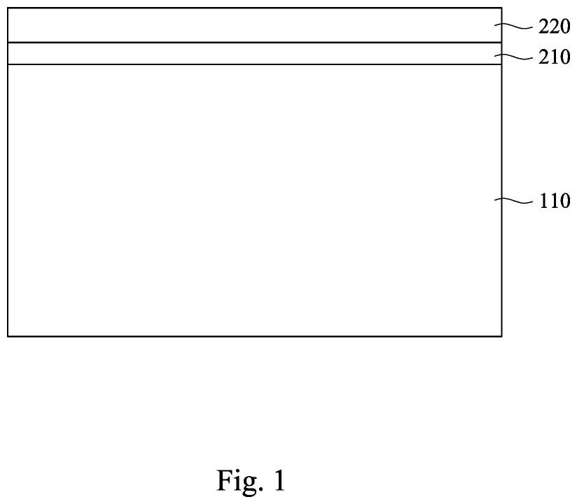

Reference is made to FIGS. 1 through 16E to illustrate the formation of a semiconductor structure 100 according to one or more embodiments of the present disclosure, wherein the formed semiconductor structure 100 may be used as a memory device.

FIG. 1 is a schematic cross-section view of forming an anti-reflective layer 210 and a hard mask 220 over a substrate 110 according to one or more embodiments of the present disclosure. In one or more embodiments of the present disclosure, the substrate 110 may be a semiconductor substrate, e.g., a silicon substrate. The anti-reflective layer 210 may be a silicon oxide layer formed by a thermal process. The hard mask 220 may be a tetraethoxysilane (TEOS) layer deposited over the anti-reflective layer 210.

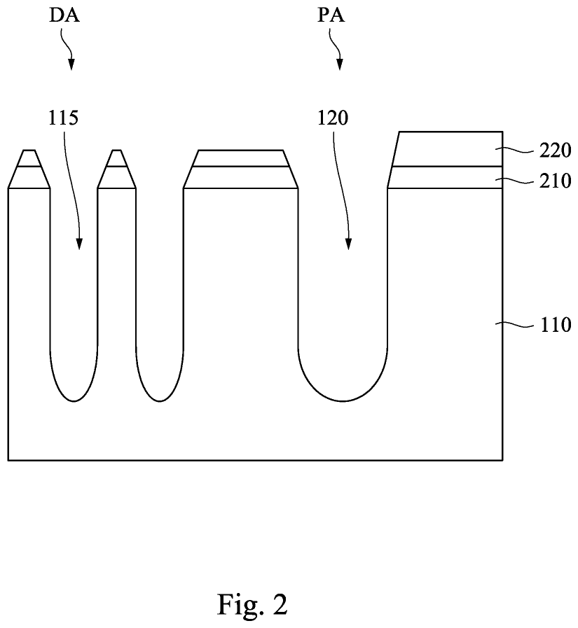

FIG. 2 is a schematic cross-section view of patterning the hard mask 220 and etching the substrate 110 based on the patterned hard mask 220 according to one or more embodiments of the present disclosure. In one or more embodiments of the present disclosure, a photoresist layer may be formed over the hard mask 220 and developed to have a design pattern. The hard mask 220 is then etched by the developed photoresist layer so that the design pattern of the developed photoresist layer is transferred to the hard mask 220. After the hard mask 220 is patterned, the substrate 110 is etched based on the patterned hard mask 220. A plurality of isolation trenches 115 and 120 is formed over the substrate 110 and recessed from a top surface of the substrate 110. In some embodiments, the isolation trenches 115 and 120 in the substrate 110 may be formed by a dry etching process. The isolation trenches 115 and 120 may be used for accommodating isolation structures.

As shown in FIG. 2, the design pattern of the hard mask 220 may further define a device area DA and a peripheral area PA out of the device area. The isolation trenches 115 in the device area DA may be used to define active regions for word line structures in a memory device. A plurality of peripheral circuits connected to elements (e.g., word line structures) may be formed in the peripheral area PA, and the isolation trench 120 may be used to isolate the peripheral circuits in the peripheral area PA. In some embodiments, as illustrated in FIG. 2, a width of each isolation trench 115 is less than a width of the isolation trench 120. A density of the isolation trenches 115 in the device area DA is greater than a density of the isolation trench 120 in the peripheral area PA.

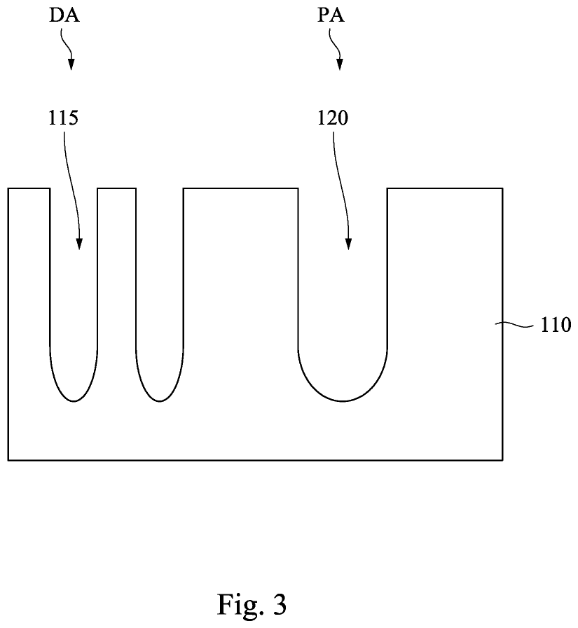

FIG. 3 is a schematic cross-section view of removing the hard mask 220 and the anti-reflective layer 210 according to one or more embodiments of the present disclosure. After the isolation trenches 115 and 120 are formed, the hard mask 220 and the anti-reflective layer 210 are removed. In some embodiments, the hard mask 220 of TEOS and the anti-reflective layer 210 of silicon oxide may be removed by a dry etch post-clean process and a wet chemical removal process for the hard mask 220 of TEOS.

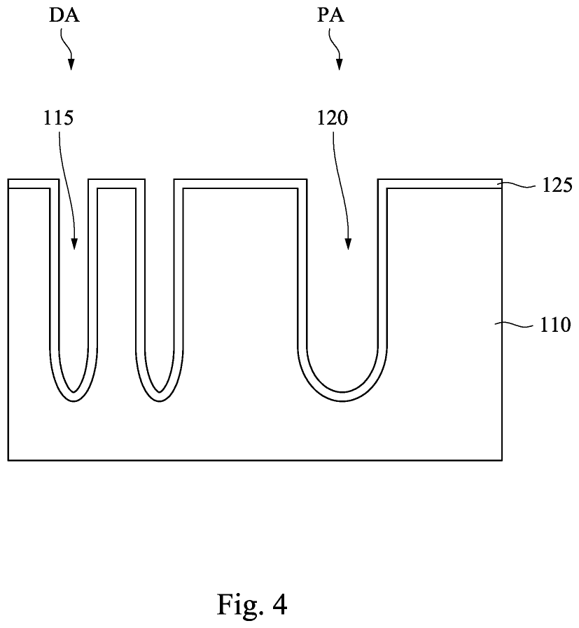

FIG. 4 is a schematic cross-section view of forming a semiconductor layer 125 over the top surface of the substrate 110 and in the isolation trenches 115 and 120 according to one or more embodiments of the present disclosure. In some embodiments, the formation of the semiconductor layer 125 may be used to enlarge areas of the active regions in the device area DA. The material of the semiconductor layer 125 may be the same as the material of the substrate 110. In this embodiment, the substrate 110 is a silicon substrate and the semiconductor layer 125 is a silicon thin film deposited over the substrate 110.

The formed semiconductor layer 125 may be regarded as an extension of the substrate 110. After the semiconductor layer 125 is formed, the isolation trenches 115 and 120 may be redefined as trenches extending downwardly from a top surface of the semiconductor layer 125 into the substrate 110.

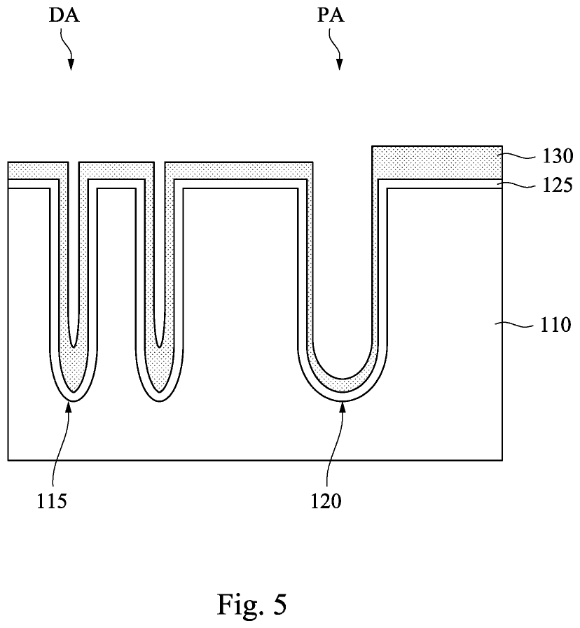

FIG. 5 is a schematic cross-section view of forming a first oxide layer 130 over the semiconductor layer 125 according to one or more embodiments of the present disclosure. In this embodiment, the first oxide layer 130 is a silicon oxide layer. In one or more embodiments of the present disclosure, the first oxide layer 130 of the silicon oxide layer may be formed by oxidizing a silicon layer following depositing the silicon layer over the semiconductor layer 125.

As shown in FIG. 5, a top surface of the first oxide layer 130 adjacent the isolation trench 120 in the peripheral area PA is higher than a top surface of the first oxide layer 130 adjacent the isolation trenches 11 in the device area DA because of the loading effect of the first oxide layer. Since a width of each isolation trench 115 is less than a width of the isolation trench 120 and a density of the isolation trenches 115 in the device area DA is greater than a density of the isolation trench 120 the peripheral area PA, a deposition amount of the first oxide layer 130 in device area DA is less than a deposition amount of the first oxide layer 130 in the peripheral area PA.

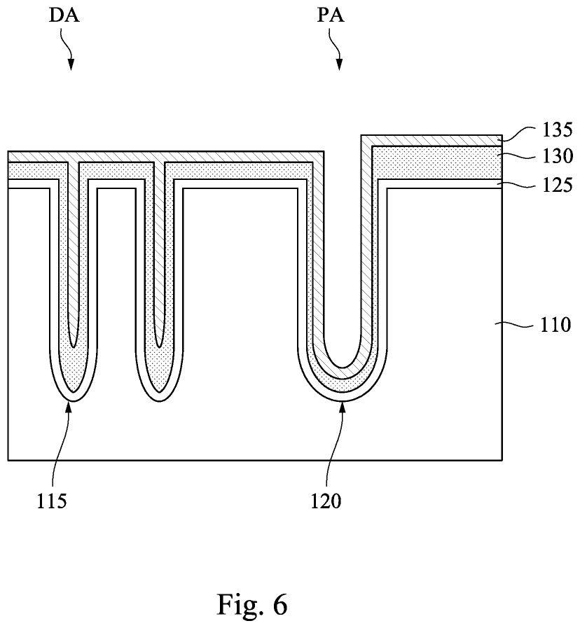

FIG. 6 is a schematic cross-section view of forming a liner 135 over the first oxide layer 130 according to one or more embodiments of the present disclosure. In this embodiment, the liner 135 may be a silicon nitride layer conformally deposited over the first oxide layer 130 of silicon oxide. In some embodiments, the liner 135 may be an oxygen-free layer over the first oxide layer 130.

In FIG. 6, the isolation trenches 115 are filled with the first oxide layer 130 and the liner 135 in the device area DA, and the isolation trench 120 in the peripheral area PA is not filled with the first oxide layer 130 and the liner 135 since the width of the isolation trench 120 is greater than the width of each of isolation trench 115.

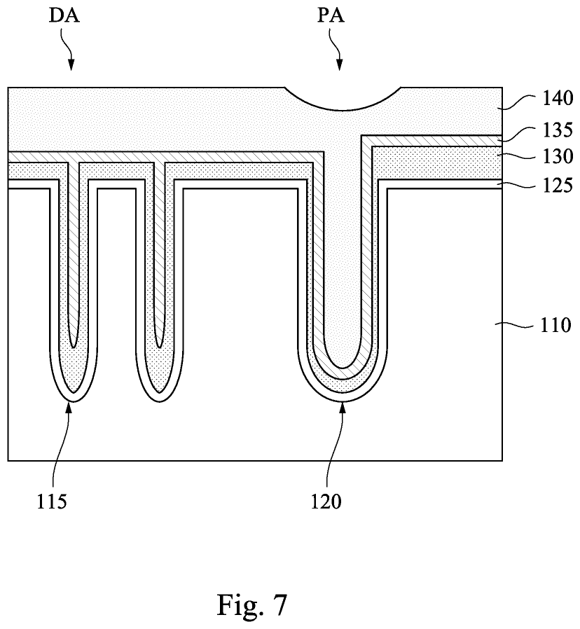

FIG. 7 is a schematic cross-section view of forming a second oxide layer 140 over the liner 135 according to one or more embodiments of the present disclosure. In this embodiment, the second oxide layer 140 may be silicon oxide conformally deposited over the liner 135 of silicon nitride. In FIG. 7, the isolation trench 120 in the peripheral area PA is filled with the first oxide layer 130, the liner 135 and the second oxide layer 140 after the second oxide layer 140 is formed. The second oxide layer 140 has a recess recessed from a top surface of the second oxide layer 140 and is aligned with the isolation trench 120.

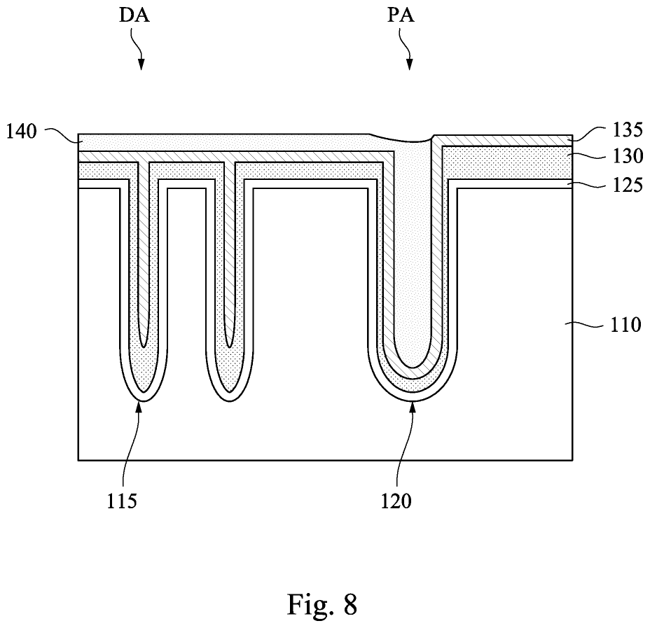

FIG. 8 is a schematic cross-section view of polishing the second oxide layer 140 according to one or more embodiments of the present disclosure. In this embodiment, after the second oxide layer 140 of silicon oxide is formed, a chemical mechanical polishing (CMP) process is performed on the second oxide layer 140. The CMP process to the second oxide layer 140 stops at the top surface of the liner 135 of silicon nitride according to the polishing rate difference between the second oxide layer 140 and the liner 135.

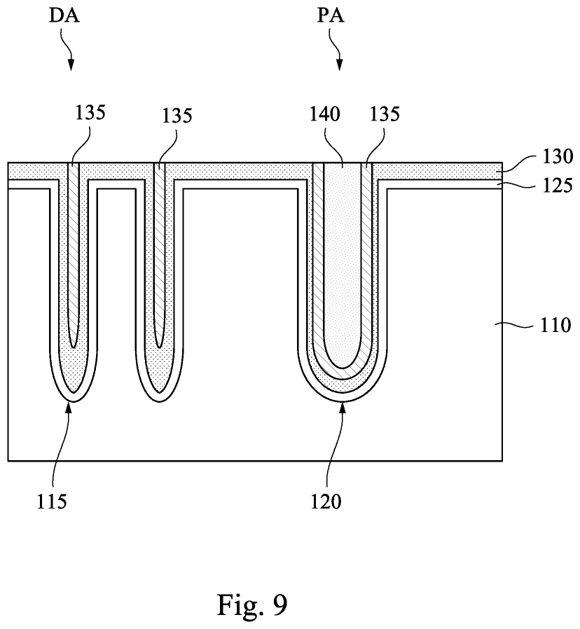

FIG. 9 is a schematic cross-section view of etching the first oxide layer 130, the liner 135 and the second oxide layer 140 according to one or more embodiments of the present disclosure. In this embodiment, the first oxide layer 130 and the second oxide layer 140 are silicon nitride and the liner 135 is silicon nitride, and an etching process with low etch selectivity for silicon oxide and silicon nitride is performed on the first oxide layer 130, the liner 135 and the second oxide layer 140.

As shown in FIG. 9, after the etching process is performed, the first oxide layer 130 and the liner 135 are exposed. The second oxide layer 140 in the device area DA is removed and the second oxide layer 140 remains in the isolation trench 120 in the peripheral area PA. The horizontal portion of the liner 135 extending over the first oxide layer 130 is removed. The remaining liner 135 has a plurality of liner portions extending from the top surface of the first oxide layer 130 into the isolation trenches 115 in the device area DA or into the isolation trench 120 in the peripheral area PA. The liner 135 remaining in the isolation trench 120 is between the first oxide layer 130 and the second oxide layer 140.

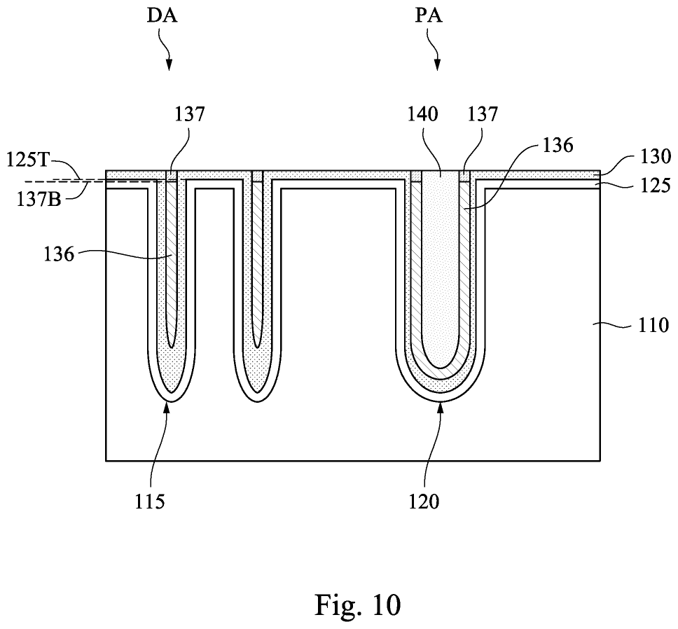

FIG. 10 is a schematic cross-section view of oxidizing the liner 135 according to one or more embodiments of the present disclosure. In one or more embodiments of the present disclosure, the liner 135 may be oxidized by a low-temperature plasma oxidation process. For example, the low-temperature plasma oxidation process for oxidizing the liner 135 may be an oxygen plasma oxidation process in a low process temperature. In this embodiment, the exposed top portions of the liner 135 of silicon nitride are oxidized and transformed into oxidized lining portions 137 of silicon oxynitride, and bottom portions of the liner 135 remain and may be regarded as unoxidized lining portion 136. It is noted that the oxidation process for the liner 135 may not change the composition of the first oxide layer 130 and the second oxide layer 140 since the first oxide layer 130 and the second oxide layer 140 are oxide.

In one or more embodiments of the present disclosure, the first oxide layer 130, the second oxide layer 140 and the oxidized lining portions 137 of the oxidized liner 135 may be oxides having similar etch rates. Etch selectivity of the liner 135, the first oxide layer 130 and the second oxide layer 140 may be reduced because of the existence of the oxidized lining portions 137.

In this embodiment, the oxidized lining portions 137 of silicon oxynitride are over the unoxidized lining portions 136 of silicon nitride. Once all of the oxidized lining portions 137 to be etched are removed, the unoxidized lining portions 136 may be exposed and have an etch rate different from the first oxide layer 130 and the second oxide layer 140. Therefore, the oxidized lining portions 137 may be designed to have enough lengths to be etched. As illustrated in FIG. 10, the lengths of the oxidized lining portions 137 extend into the isolation trenches 115 and 120. In some embodiments, the lengths of the oxidized lining portions 137 can be controlled by adjusting plasma conditions of the plasma oxidation processes, and the oxidized lining portions 137 may have more lengths extending into the isolation trenches 115 and 120. As shown in FIG. 10, a height 137B of the bottom surfaces of the oxidized lining portions 137 is lower than a height 125T of the top surface of the semiconductor layer 125.

In one or more embodiments of the present disclosure, process temperature of the plasma oxidation process for oxidizing the liner 135 may be controlled to avoid damaging the first oxide layer 130, the liner 135 and the second oxide layer 140 too much and heating the substrate 110. As shown in FIGS. 9 and 10, some of the top portions of the first oxide layer 130, the liner 135 and the second oxide layer 140 may be removed by plasma after the low-temperature plasma oxidation process for the liner 135 is performed. In some embodiments, the low-temperature plasma oxidation process for oxidizing the liner 135 may be performed at a process temperature in a range between 25° C. and 250° C.

As shown in FIG. 10, the oxidized lining portions 137 in the device area DA are between portions of the first oxide layer 130. The oxidized lining portions 137 in the peripheral area PA are between the first oxide layer 130 and the second oxide layer 140.

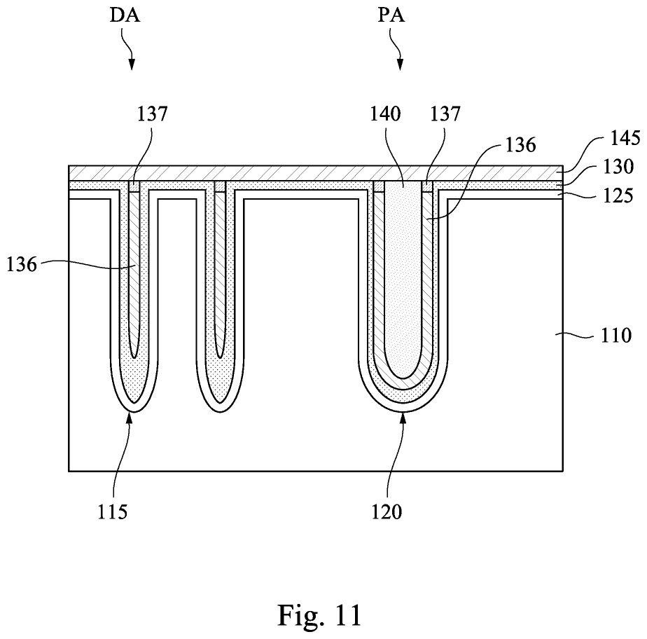

FIG. 11 is a schematic cross-section view of forming a sacrificial oxide layer 145 over the first oxide layer 130, the liner 135 (including unoxidized lining portion 136 and oxidized lining portions 137) and the second oxide layer 140 according to one or more embodiments of the present disclosure. In this embodiment, the sacrificial oxide layer 145 may be a layer of silicon oxide formed over the first oxide layer 130, the liner 135 and the second oxide layer 140 by a deposition process.

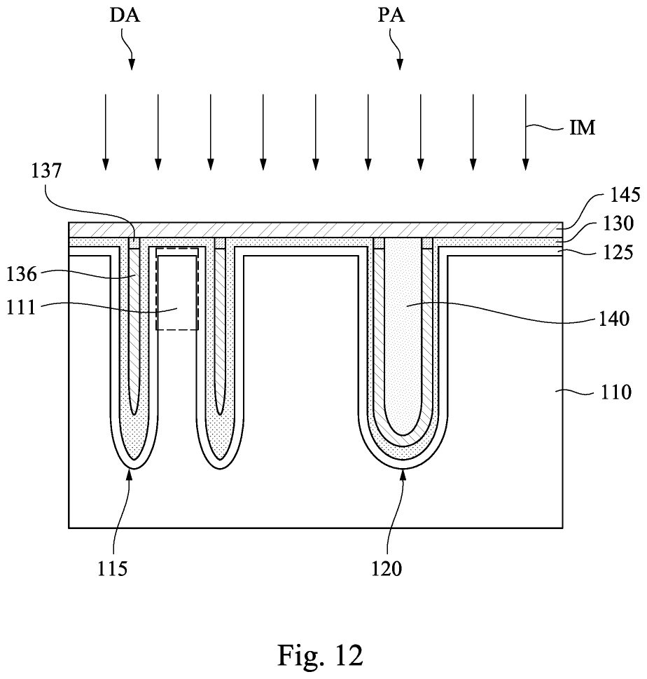

FIG. 12 is a schematic cross-section view of forming an implant region 111 over the substrate 110 according to one or more embodiments of the present disclosure. As shown in FIG. 12, an implantation process IM across the sacrificial oxide layer 145 and the first oxide layer 130 is performed to the substrate 110 and the semiconductor layer 125 to form the implant region 111 between the isolation trenches 115. In the device area DA, the first oxide layer 130 and the liner 135 form isolation structures in the isolation trenches 115, and the implant region 111 in the device area DA may be defined as one of active regions between the isolation structures in the isolation trenches 115. In some embodiments, the implant region 111 may be regarded as a semiconductor well with a semiconductor type (e.g., p-type or n-type). In some embodiments, the implant region 111 may be formed by cycles of implantation process and clean process for the sacrificial oxide layer 145.

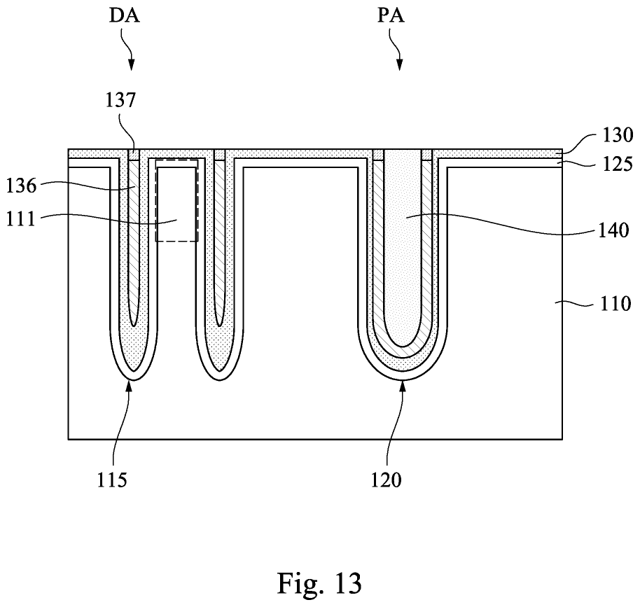

FIG. 13 is a schematic cross-section view of removing the sacrificial oxide layer 145 according to one or more embodiments of the present disclosure. After the implant region 111 is formed, the sacrificial oxide layer 145 may be removed by an etching process. In this embodiment, since the first oxide layer 130, the second oxide layer 140, the sacrificial oxide layer 145 and the oxidized lining portions 137 of the liner 135 are oxides, the etch selectivity of the etching process of the sacrificial oxide layer 145 may be reduced for the first oxide layer 130, the second oxide layer 140, the sacrificial oxide layer 145 and the oxidized lining portions 137 of the liner 135. As shown in FIG. 13, the top surfaces of the first oxide layer 130, the second oxide layer 140 and the oxidized lining portions 137 of the liner 135 may be level with each other after the sacrificial oxide layer 145 is removed.

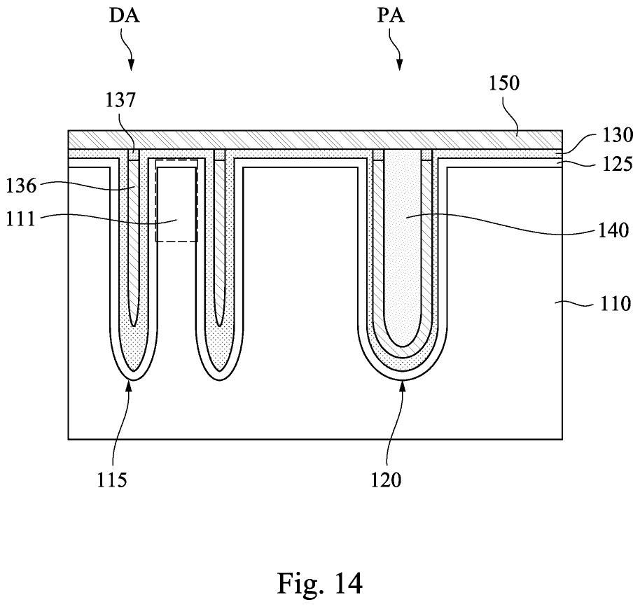

FIG. 14 is a schematic cross-section view of forming a mask layer 150 over the first oxide layer 130, the oxidized lining portions of the liner 135 and the second oxide layer 140 according to one or more embodiments of the present disclosure. In this embodiment, the mask layer 150 may be a layer of silicon nitride formed by a deposition process. The sacrificial oxide layer 145 may be used to form word line structures in the device area DA.

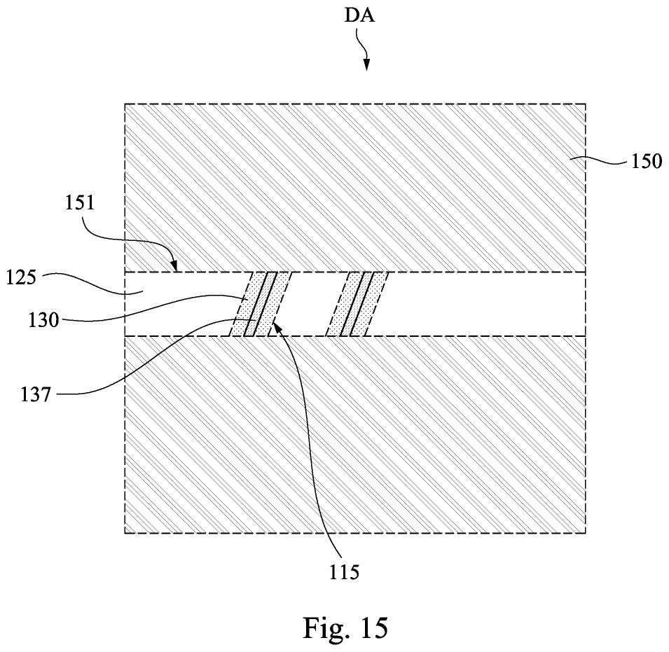

FIG. 15 is a schematic top view of patterning the mask layer 150 according to one or more embodiments of the present disclosure. FIG. 15 illustrates a schematic top view in the device area DA. In FIG. 15, the mask layer 150 is patterned and has an opening 151 exposing the semiconductor layer 125 over the substrate 110 and the isolation structures in the isolation trenches 115. The isolation structures in the isolation trenches 115 include the first oxide layer 130 and the oxidized liner 135. As shown in FIG. 15, the oxidized lining portions of the oxidized liner 135 are exposed from the opening 151 of the mask layer 150. In some embodiments, the opening 151 is free from the peripheral area PA and word line structure is not formed in the peripheral area PA.

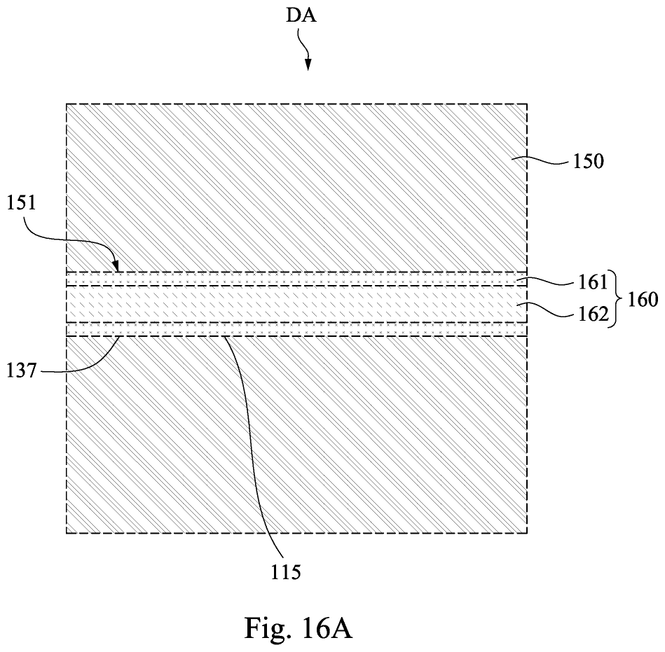

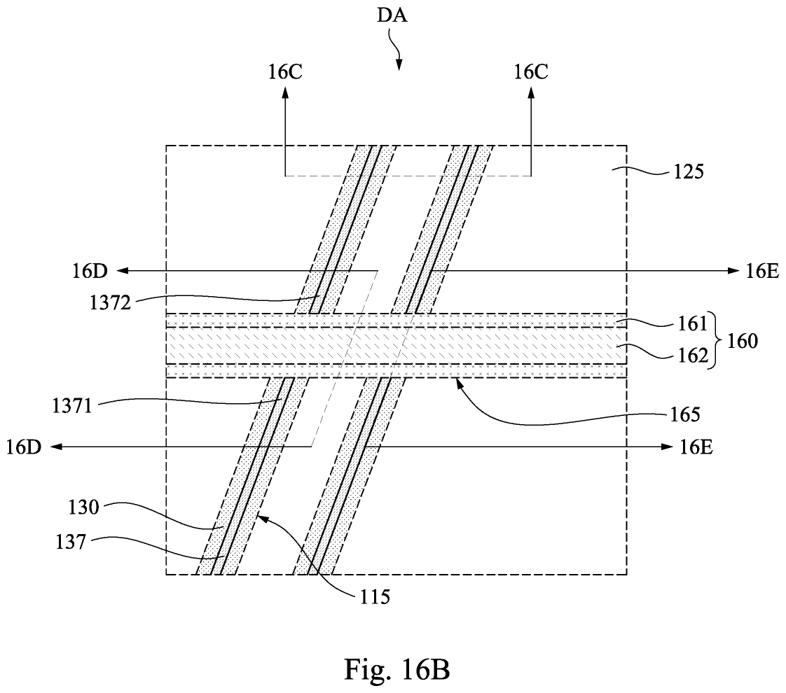

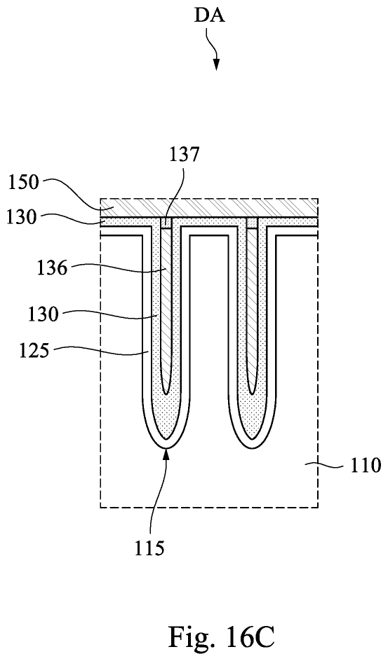

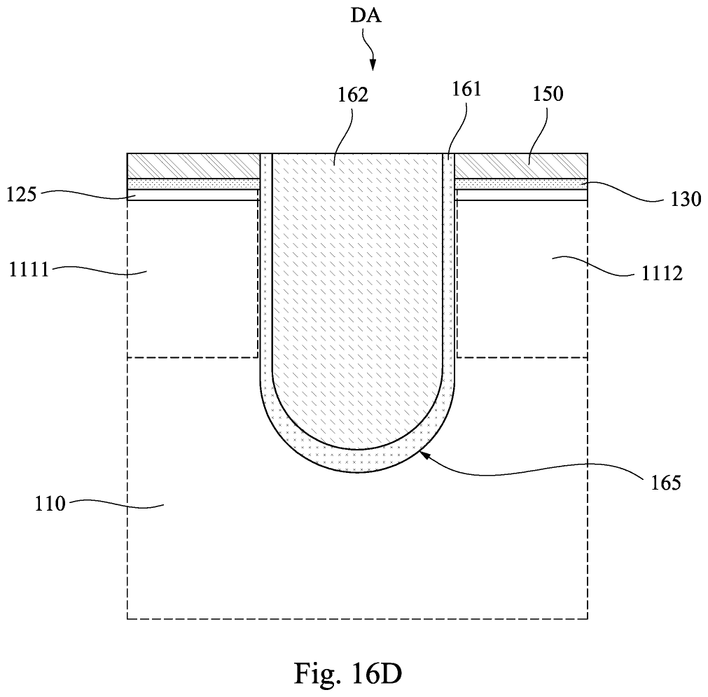

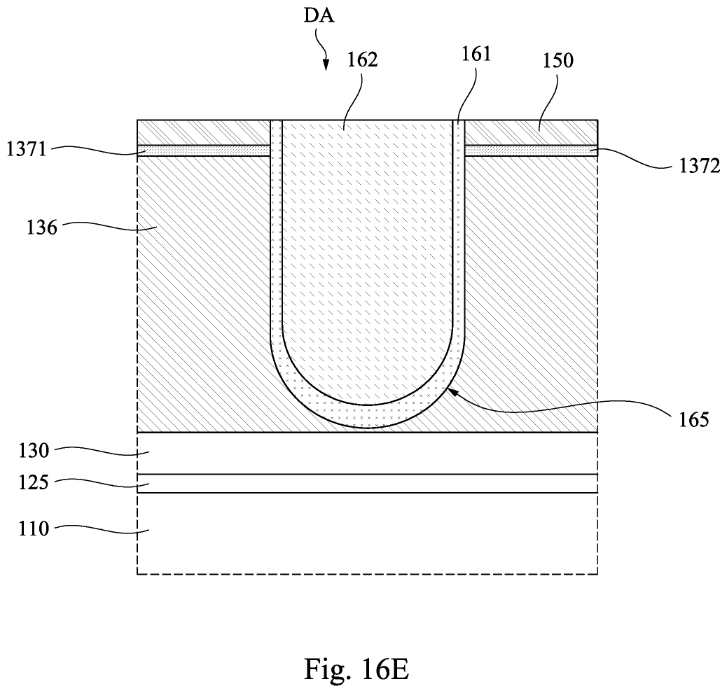

FIGS. 16A through 16E are schematic top views and cross-section views of forming a semiconductor structure 100 according to one or more embodiments of the present disclosure, wherein FIG. 16A illustrates a schematic cross-section view, and FIG. 16B illustrates a schematic cross-section view of FIG. 16A and omits the mask layer 150 higher than the top surface of the semiconductor layer 125 for clarity.

In the device area DA, after the mask layer 150 is patterned, the substrate 110, the semiconductor layer 125 and the isolation structures including the first oxide layer 130 and the liner 135 in the isolation trenches 115 are etched to form a word line trench 165 across the first oxide layer 130 and the liner 135 in the isolation trenches 115. A word line structure 160 is then formed in the word line trench 165. The word line structure 160 includes a dielectric layer 161 in the word line trench 165 and a conductive layer 162 over the dielectric layer 161. After the word line structure 160 is formed, the semiconductor structure 100 is provided and includes the isolation structures of the first oxide layer 130 and liner 135 in the isolation trenches 115, and the word line structure 160 in the word line trench 165.

After the word line structure 160 is formed, the mask layer 150 remaining over the semiconductor layer 125 may be used as a mask layer for forming a bit line or a dielectric layer covering the semiconductor layer 125.

As shown in FIGS. 16B and 16E, each oxidized lining portion 137 of the oxidized liner 135 is cut off into two separated oxidized lining portions 1371 and 1372. FIG. 16E illustrates a schematic cross-section view along the two separated oxidized lining portions 1371 and 1372.

FIG. 16C illustrates a schematic cross-section view along two adjacent isolation structures in the isolation trenches 115, and the oxidized lining portions 137 of the liner 135 remain in the semiconductor structure 100.

FIG. 16D illustrates a schematic cross-section view across the word line structure 160 and the implant region 111. In FIG. 16D, the implant regions 111 are cut off into two separated implant regions 1111 and 1112. In some embodiments, the implant regions 1111 and 1112 may be used as source/drain regions, the dielectric layer 161 and the conductive layer 162 of the word line structure 165 form a gate structure, and the source/drain regions of the implant regions 1111, 1112 and the gate structure of the dielectric layer 161 and the conductive layer 162 form a transistor in the device area DA. In one or more embodiments of the present disclosure, more numbers of the implant regions 111 and the word line structure 160 may be formed in the device area DA to form an array of transistors used for a memory device.

In summary, in one or more embodiments of the present disclosure, an oxidation process may be performed on the liner in the isolation structure. The oxidized portion of the liner and the oxide layer can have similar etching rates. Therefore, after the mask layer is subsequently formed on the isolation structure, few or no unintended bump is formed on the mask layer. The oxide layer and the liner can have similar remaining heights after performing the etching process on the oxide layer and the oxidized liner. The design pattern of the memory device may not be damaged and additional planarization processes on the mask layer over the isolation structure can be saved.

Although the embodiments of the present disclosure have been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the embodiments of the present disclosure without departing from the scope or spirit of the present disclosure. In view of the foregoing, it is intended that the present disclosure cover modifications and variations of this disclosure provided they fall within the scope of the following claims.

What is claimed is:

1. A method comprising:
forming an oxide layer in an isolation trench over a substrate;
forming a liner over the oxide layer;
oxidizing the liner;
forming an implant region over the substrate after the liner is oxidized;
etching the oxide layer and the liner after the implant region is formed; and
forming a word line structure over the substrate and across the oxide layer and the liner.

2. The method of claim 1, wherein the liner is oxidized to have an unoxidized lining portion and an oxidized lining portion over the unoxidized lining portion, and the oxidized lining portion extends into the isolation trench.

3. The method of claim 1, further comprising:
forming a semiconductor layer over the substrate and in the isolation trench, wherein the liner is oxidized to have an unoxidized lining portion and an oxidized lining portion over the unoxidized lining portion, and the oxidized lining portion has a bottom surface lower than a top surface of the semiconductor layer.

4. The method of claim 1, further comprising:
forming a sacrificial oxide layer over the oxide layer and the liner after the liner is oxidized, wherein the implant region is formed by an implantation process across the sacrificial oxide layer.

5. The method of claim 1, further comprising:
forming a hard mask over the oxide layer and the liner;
patterning the hard mask so that the oxide layer and an oxidized lining portion of the liner is exposed; and
etching a word line trench across the oxide layer and the liner based on the hard mask, wherein the word line structure is formed in the word line trench.

6. The method of claim 5, wherein the word line trench is etched so that an oxidized lining portion of the liner is cut off into a first portion and a second portion separated from each other.

7. The method of claim 1, wherein the liner is an oxygen-free layer before the liner is oxidized.

8. A method comprising:
forming a plurality of isolation trenches over a substrate;
forming a first oxide layer over the isolation trenches;
forming a liner over the first oxide layer;
forming a second oxide layer over the liner;
polishing the second oxide layer so that the first oxide layer and the liner are exposed;
oxidizing the liner;
forming an implant region in the substrate; and
forming a word line structure over the substrate and across the isolation trenches.

9. The method of claim 8, wherein the liner is oxidized to have unoxidized lining portions and oxidized lining portions over the unoxidized lining portions, and the oxidized lining portions extend into the isolation trenches.

10. The method of claim 9, wherein after the word line structure is formed, the second oxide layer remains and is between the oxidized lining portions in one of the isolation trenches in a peripheral area free from the word line structure.

11. The method of claim 8, further comprising:
forming a sacrificial oxide layer over the first oxide layer, the liner and the second oxide layer after the liner is oxidized, wherein the implant region is formed by an implantation process across the sacrificial oxide layer.

12. The method of claim 8, further comprising
forming a hard mask over the first oxide layer and the liner;
patterning the hard mask so that the first oxide layer and oxidized lining portions of the liner is exposed; and
etching a word line trench across the first oxide layer and the liner based on the hard mask, wherein the word line structure is formed in the word line trench.

13. The method of claim 8, wherein the liner is an oxygen-free layer before the liner is oxidized.

14. A semiconductor structure comprising:
a first isolation region over a substrate, wherein the first isolation region comprises a first oxide layer and a first liner over the first oxide layer, and the first liner has a first unoxidized lining portion and a first oxidized lining portion over the first unoxidized lining portion; and
a word line structure across the first isolation region, wherein a first portion and a second portion of the first oxidized lining portion are separated from each other by the word line structure.

15. The semiconductor structure of claim 14, further comprising:
a second isolation region over the substrate, wherein the second isolation region comprises a second liner with a second oxidized lining portion, and a first portion and a second portion of the second oxidized lining portion are separated from each other by the word line structure.

16. The semiconductor structure of claim 15, further comprising:
an active implant region between the first oxidized lining portion of the first liner and the second oxidized lining portion of the second liner.

17. The semiconductor structure of claim 14, further comprising:
a second isolation region over the substrate, wherein the second isolation region comprises a second oxide layer, a second liner over the second oxide layer and a third oxide layer over the second liner, the second liner has a second unoxidized lining portion and a second oxidized lining portion over the second unoxidized lining portion, and the second oxidized lining portion is between the second oxide layer and the third oxide layer.

18. The semiconductor structure of claim 17, wherein the second isolation region is free from the word line structure.

19. The semiconductor structure of claim 14, wherein a material of the first oxidized lining portion is different from a material of the first oxide layer.

20. The semiconductor structure of claim 14, further comprising:
a semiconductor layer over the substrate, wherein a bottom surface of the first oxidized lining portion is lower than a top surface of the semiconductor layer.
